(19) United States
(12) Patent Application Publication
(10) Pub. No.: US 2016/0150594 A1
(43) Pub. Date: May 26, 2016

(54) Thermocompression bonding apparatus and method

(71) Applicants: Stephen P. NOOTENS, San Diego, CA (US); Frank J. POLESE, San Diego, CA (US); Christopher H. BATEMAN, San Diego, CA (US); Sorin DIENSCU, San Diego, CA (US); Casey C. CLAUSEN, San Diego, CA (US); William L. BRADBURY, San Diego, CA (US); Donald M. BECHELDER, San Diego, CA (US); Jonathan H. HARRIS, San Diego, CA (US); Robert J. TESCH, San Diego, CA (US)

(72) Inventors: Stephen Nootens, San Diego, CA (US); Frank J. Polese, San Diego, CA (US); Christopher H. Bateman, San Diego, CA (US); Sorin Dinescu, San Diego, CA (US); Casey C. Clausen, Portland, OR (US); William L. Bradbury, San Diego, CA (US); Donald L. Bachelder, Escondido, CA (US); Jonathan H. Harris, Scottsdale, AZ (US); Robert J. Tesch, Phoenix, AZ (US)

(21) Appl. No.: 14/902,973

(22) PCT Filed: Jul. 3, 2014
(86) PCT No.: PCT/US2014/045483

§ 371 Date: Jan. 5, 2016

Related U.S. Application Data
(63) Continuation of application No. 14/192,787, filed on Feb. 27, 2014.
(60) Provisional application No. 61/843,302, filed on Jul. 5, 2013.

(51) Int. Cl. H05B 3/26; H01L 23/00; H01C 17/00

(52) U.S. Cl. CPC H05B 3/26; H01C 17/00; H01L 24/16

(57) ABSTRACT

A multi-layer aluminum nitride ceramic, multi-heating element substrate (11) is provided for forming electrical bonds between integrated circuits (13) and an interposer structure (14) using a thermocompression bonding process. The individually energizable heater element traces (9) can be run through common regions of the heater surface platform (5). A network of cooling vias can be run through other parts of the substrate. The traces are then separately controlled and energized during a predetermined routine resulting in a temperature profile that maintains a substantially constant temperature plateau phase near a reflow temperature, and a more uniform temperature across the spaced apart surface regions of the heater substrate, thus imparting a more precisely uniform heating to the parts being bonded.

### PRIOR APPLICATION

This application is a continuation of U.S. patent application Ser. No. 14/192,787, filed 27 Feb. 2014, incorporated herein by reference, which claims the benefit of U.S. Provisional Patent Application Ser. No. 61/843,302 filed 5 Jul. 2013 incorporated herein by reference.

### FIELD OF THE INVENTION

The instant invention relates to microelectronics manufacturing and more particularly to electronic heaters useful in integrated circuit packaging and the thermocompression bonding of the electrical contacts between microelectronic components.

### BACKGROUND

The microelectronics industry is constantly striving for further miniaturization of components to increase speed and functionality of electronic systems. This has led to the fabrication of highly complex integrated circuits (ICs) on chips of semiconductors such as silicon. In order to more effectively electrically connect these chips with printed circuit boards used in many small electronic systems such as smart phones, many processing techniques and apparatuses have been developed.

To improve fabrication yield, it is often desirable to replace a single larger IC chip with a plural number of smaller chips which can be interconnected to function equivalently to the larger chip. This in turn requires the denser packaging of the smaller chips into a single mountable package.

As shown in Tung, U.S. Pat. No. 6,681,982, incorporated herein by reference, a plurality of IC chips can be densely mounted upon a substrate silicon interposer structure which in turn can be mounted upon a larger scale package substrate such as a ball grid array (BGA) to form a microelectronic package mountable to a printed circuit board (PCB).

One common type of package using a silicon interposer between the package BGA and the individual chips is a so-called copper or solder bump or pillar-type package. As disclosed in Lin et at., U.S. Pat. No. 8,021,921, the high density and small geometries of the fine-pitch, micro bump electrical contact copper pillars on the chips requires highly precise and accurate alignment and heating during the bonding of the pillars to the contact pads on the interposer.

One way to form bonds between these types of chips and the silicon interposer structure is by using a thermocompression bonding technique known in the art.

Preferably, while the chip is being pressed on the interposer to help improve flatness during bonding, the temperature is rapidly ramped up to a temperature in which reflow of the conductive pillar material, such as copper tinned with AuSn solder for example, begins. The reflowing pillars each form a bond to their respective electrically conductive pads on the interposer. Simultaneously, as reflow begins, the mechanical resistance to compression by the chip and interposer reduces, whereupon the compressive force is removed, and the chip and interposer are slightly withdrawn from one another so that the pillars do not collapse. The temperature is then brought below the reflow temperature to freeze the pillars bonded to their pads on the interposer. Because of the small geometries involved and the large number of spaced apart pillars which should be briefly and simultaneously reflowed, maintaining adequately uniform temperatures across the entire area of contact between the interposer and chips is important and can be difficult to achieve.

Typically, heat is applied to the chip on its surface opposite the surface being bonded to the chips. The ideal heating profile 1 for many applications is shown in FIG. 1 where there is a ramp portion 2 of a linear increase in temperature over time, transitioning to a plateau portion 4 at or near the reflow temperature 3. Once reflow is detected the temperature is reduced 5 primarily through active flow of a cooling medium such as a fluid such as air over radiative structures contacting the chip, interposer, and/or their mounts. Achieving the ideal heating profile even over a small portion of the surface area of the chip-to-interposer interface can be difficult given other manufacturing exigencies.

Another problem with the above thermocompression bonding technique is that the heating profile cannot be controlled uniformly across the surface of the heater, leading to disuniform heating and non-simultaneous reflow of the pillars and thus inferior bonds.

For example, a single evenly spaced heater element run near the surface of a heater platform carrying the parts to be bonded will tend result in a hotter center region of the surface and a cooler edge region of the surface. In addition, such an element could tend create an initial, transient elevated temperature beyond the target reflow temperature during the intended plateau phase of the profile. In other words, it is difficult to obtain a flat, relatively constant temperature during the intended plateau phase of the profile.

Another problem involves precisely and accurately measuring the temperature of each portion of the surface area of the chip-to-interposer interface. Prior designs have employed thermocouples to measure the temperature. However, due to the highly dynamic, rapidly changing character of the ideal heating profile, thermocouple performance can be inadequate.

Desai, U.S. Pat. No. 4,799,983, incorporated herein by reference, teaches that a multilayer ceramic (MLC) technology can be used to form heater element traces in a ceramic substrate. In general, MLC technology involves mixing particles of high temperature-withstanding dielectric material such as alumina with an organic binder, which is then tape-cast, dried and separated into a number of flexible “green sheets”. Some of the sheets are screened and printed with metalization and other circuit patterns which, when stacked in alignment with other sheets, can form intricate three-dimensional electronic interconnects. The stacked sheets are laminated together at a predetermined temperature and pressure, and then slowly heated in a binder burn-off routine to about 400 degrees C. which vaporizes off a majority of the binder material. The resultant fragile baked out or debound part is then fired at an elevated temperature routine, typically reaching 1,600 degrees C. for alumina ceramic in a reducing atmosphere such as humidified hydrogen-nitrogen upon which any residual amount of the binder material vaporizes off while the remaining material fuses or sinters into a solid ceramic body having electrical circuitry coursing therethrough. Where alumina is generally used as the electrically insulating material, and refractory metals such as tungsten and molybdenum can be used for metallization. However, since tungsten oxidzizes readily in co-firing processes involving free oxygen, care must be taken to hermetically isolate tungsten traces. During sintering the body typically shrinks about 15 to 18% where alumina is the ceramic material.

Many potential problems are faced by a designer of a thermocompression bonding heater used for densely packed microelectronic packages. Areas of particular consideration include high operating temperatures, rapidly changing temperatures, high mechanical stresses induced by the compression forces which can exceed 300 Newtons per square inch, and the tendency for tungsten to rapidly oxidize in the presence of essentially any air when heated to such high temperatures. Increasing the mass of the heater helps ruggedness at the expense of rapid heating and cooling.

Another potential problem involves different dice having different masses and geometries. This often creates dice requiring far different heating requirements which in turn can lead to requiring many different heaters.

Another consideration involves the potential thermal expansion mismatches between the ceramic substrate and the metalization. The coefficient of thermal expansion (“CTE”) or simply the thermal expansion of a material is defined as the ratio of the change in length per degree Centigrade to the length at 25 degrees C. It is usually given as an average value over a range of temperatures.

One way of overcoming some of the above problems involves using Aluminum Nitride (hereinafter referred to as “AlN”) as the ceramic. The thermal expansion of tungsten and AN are similar at approximately 4.5 ppm/degree C. Further AN can readily form hermetic structures using MLC technology. For a MLC structure formed using AN as the ceramic, shrinkage during sintering is typically between 20 to 25%.

Another consideration involves the thermal conductivity of the materials in the heater and package components being thermocompression bonded. The thermal conductivity (“K” or “TC”) of a material is defined as the time rate of heat transfer through unit thickness, across unit area, for a unit difference in temperature or K=WL/AT where W=watts, L=thickness in meters, A=area in square meters, and T=temperature difference in degrees centigrade. A more highly thermally conductive structure will tend to spread heat increasing thermal uniformity on the part being bonded and reducing thermal stress within the heater/cooler allowing for increased ramp rates. Typically, to enhance uniformity across the area of the part being reflowed it is desirable to have higher TC near the part. Further, it is often desirable to have a lower TC between the heater and supportive structures in order to form a thermal break between the heater and those structures which may act as a heat sink.

The instant invention results from efforts to improve thermal control of a heater substrate used in thermocompression bonding of microelectronic components.

### SUMMARY

The primary and secondary objects of the invention are to provide an improved thermal control in a thermocompression bond forming heater substrate. These and other objects are achieved by a plural number of separately energizable heater element traces in a thermocompression bonding substrate.

The content of the original claims portion is incorporated herein by reference as summarizing features in one or more exemplary embodiments.

In some embodiments there is provided a solid state electrical heater apparatus for heating the surface of a part, said apparatus comprises: a part-contacting platform; said platform including a medial zone and a peripheral region laterally spaced a distance apart form said medial zone; a first heater element coursing along and being in thermal communication with said zone; a second heater element spaced apart from said first heater element; said second heater element coursing along and being in thermal communication with said region; and, wherein said first and second heater elements are separately energizable.

In some embodiments the apparatus further comprises: said first element coursing along both said zone and said region; and said second element coursing along both said zone and said region.

In some embodiments said first heater element disproportionately heats said zone more than said region over a given time frame; and, wherein said second heater element is adapted to provide proportionately greater heat flux to said region than said zone during a given energization period.

In some embodiments said first heater element comprises a first trace having a first circuitous pattern, and wherein said second heater element comprises a second trace having a second circuitous pattern.

In some embodiments said second circuitous pattern comprises a first pair of adjacent runs spaced apart by said first shortest distance and a second pair of adjacent runs spaced apart by a second shortest distance, wherein said first and second shortest distances are different.

In some embodiments said second circuitous pattern comprises: a first run having a first smallest cross-sectional area; and, a second run having a second smallest cross-sectional area, wherein said first and second smallest cross-sectional areas are different.

In some embodiments said first and second heater traces are coplanar and laterally spaced apart and wherein said second trace surrounds said first trace.

In some embodiments said first heater element is energized according to a first operation routine, and wherein said second heater element is energized according to a second operation routine, wherein operation of said heater elements simultaneously according to said routines results in a temperature difference across said platform of no greater than plus or minus 3 percent.

In some embodiments said first heater element is energized according to a first operation routine, and wherein said second heater element is energized according to a second operation routine, wherein operation of said heater elements simultaneously according to said routines results in a temperature difference across said platform of no greater than plus or minus 2 percent.

In some embodiments said first operation routine comprises a first heater element ramp up phase followed by a first heater element plateau phase followed by a first heater element ramp down phase; wherein said second operation routine comprises a second heater element ramp up phase followed by a second heater element ramp down phase.

In some embodiments said second heater element ramp down phase begins before or during said first heater element plateau phase.

In some embodiments the apparatus further comprises: said first heater element being energized during a portion of said plateau phase at no more than a constant plateau power level; said second heater element operation routine comprising a second heater element maximum power level; and, said maximum power level being greater than said constant plateau power level.

In some embodiments said first trace has a substantially planar first geometry commensurately overlaying a substantially planar second geometry of said second trace.

In some embodiments the apparatus further comprises a RTD trace having a substantially planar geometry commensurately overlaying with said first geometry, interposed between said first heater trace and said surface.

In some embodiments the apparatus further comprises: a first grounding trace coursing along both of said region and said zone.

In some embodiments the apparatus further comprises: said heater being formed by a plurality of multilayer ceramic layers comprising: aluminum nitride; and, said traces comprising tungsten.

In some embodiments the apparatus further comprises: a first vacuum channel extending from said platform through a plurality of said layers.

In some embodiments the apparatus further comprises: a plurality of vacuum grooves emanating from said channel toward spaced apart regions of said platform.

In some embodiments the apparatus further comprises at least one conduit extending through a plurality of adjacently stratified ones of said layers, wherein said at least one conduit is adapted to carry a cooling fluid.

In some embodiments said cooling fluid comprises air.

In some embodiments the apparatus further comprises a network of cooling vias extending through a plurality of adjacently stratified ones of said layers, wherein said network is adapted to carry a cooling fluid comprising air.

In some embodiments said network comprises: a reservoir; a supply manifold leading from a source of cooling fluid to said reservoir; and, an exhaust manifold from said reservoir to an exhaust return.

In some embodiments said supply manifold comprises: a trunk portion; a plurality of branch portions emanating from said trunk portion; and, wherein each one of said branch portions includes a plurality of spaced apart feeder ducts leading between said one of said branch portions and said reservoir.

In some embodiments said second circuitous pattern comprises a plurality of interconnected, spaced apart runs wherein a spacing between adjacent runs progressively increases between said medial zone and said peripheral region.

In some embodiments said second circuitous pattern comprises a continuous flat spiral segment.

In some embodiments said second circuitous pattern comprises a continuous serpentine segment.

In some embodiments said continuous serpentine segment comprises: a set of parallel lines; and, perpendicular sections linking said lines.

In some embodiments the apparatus further comprises: said first circuitous pattern being topographically similar to the second circuitous pattern; wherein said first circuitous pattern has trace lines substantially perpendicular to the parallel lines of said second pattern; and, an electrically insulating layer between said patterns.

In some embodiments there is provided a thermocompression bonding apparatus comprises: a heater substrate; wherein said substrate comprises: a substantially planar part-carrying upper surface having a medial zone and a peripheral region laterally spaced a distance apart form said medial zone; and, a first heater element coursing under both of said region and said zone; a first cooling conduit coursing under both of said region and said zone; wherein said element comprises: a first trace having a first circuitous pattern having a first segment coursing along said zone and a second segment coursing along said region; wherein said first segment generates a first heat flux during an energization period, and wherein said second segment simultaneously generates a second heat flux during said energization period; wherein said second flux is greater than said first flux; whereby a unit area of said zone has a first temperature and a unit area of said region simultaneously has second temperature; wherein said first and second temperatures are within about 3 percent of one another.

In some embodiments there is provided a further comprises: said second segment has an electrical resistance per unit length of trace greater than said first segment.

In some embodiments the apparatus further comprises a network of cooling vias extending through a plurality of adjacently stratified ones of said layers, wherein said network is adapted to carry a cooling fluid comprising air.

In some embodiments said network comprises: a reservoir; a supply manifold leading from a source of cooling fluid to said reservoir; and, an exhaust manifold from said reservoir to a an exhaust return.

In some embodiments said supply manifold comprises: a trunk portion; a plurality of branch portions emanating from said trunk portion; and, wherein each one of said branch portions includes a plurality of spaced apart feeder ducts leading between said one of said branch portions and said reservoir.

In some embodiments the apparatus further comprises: a second heater element spaced apart for said first heater element.

In some embodiments the apparatus further comprises: said second heater element coursing under both of said region and said zone; and, wherein said first and second heater elements are separately energizable.

In some embodiments the apparatus further comprises: said first heater element comprising a first serpentine trace residing substantially within a first plane; said second heater element comprising a second serpentine trace residing substantially within a second plane; said first plane being parallely spaced apart from said second plane.

In some embodiments there is provided a method of controlling the temperature of a thermocompression bonding heater substrate, said method comprises: selecting a heater substrate comprising: a substantially planar operational surface comprising a medial zone and a peripheral region spaced a lateral distance apart from said medial zone; a first heater element trace coursing along said zone; a second heater element trace spaced apart for said first heater element trace; said second heater element trace coursing along said region; and, wherein said first and second traces are separately energizable; energizing said first trace according to a center-biased energization routine; simultaneously energizing said second trace according to a perimeter-biased energization routine; and, ceasing energizing one of said traces during a time when the other of said traces is being energized; whereby the simultaneous temperatures of said region and said zone are kept within about 3 percent of one another.

In some embodiments the method further comprises: said first trace coursing along both said zone and said region; and said second trace coursing along both said zone and said region.

In some embodiments the method further comprises: said center-biased energization routine having a plateau phase.

In some embodiments there is provided a thermocompression bonded structure comprises: an interposer; at least one integrated circuit chip; a plurality of spaced apart conductive metal pillars electrically interconnecting said at least one chip to said interposer; wherein each of said pillars has a geometry comprising a height dimension, a top end diametric dimension, and a medial diametric dimension potentially different from one another; wherein said height dimensions range between one percent of one another; wherein said top end diametric dimensions range between one percent of one another; and wherein said medial diametric dimensions range between one percent of one another.

In some embodiments there is provided a method for optimizing the powering routine for a TCB heater, said method comprises: selecting a sintered heater blank which can be machined to form an intended heater; first grinding, lapping and polishing a platform surface of said intended heater; cutting a demarcation of a pedestal into said surface; grinding away an amount of material surrounding said pedestal; modeling a preliminary heating routine from parameters associated with said die and said intended heater; performing a test run of said intended heater using said preliminary heating routine; and, adapting said preliminary heating routine into a final heating routine based on results of said performing.

### BRIEF DESCRIPTION OF THE DRAWING

FIG. 1 is a graphical illustration of an ideal heating profile for a thermocompression bonding application in semiconductor manufacturing.

FIG. 2 is a diagrammatical exploded cross-sectional side view illustration of some major components of a thermocompression bonding apparatus according to an exemplary embodiment of the invention.

FIG. 3 is a diagrammatical cross-sectional side view illustration of the stacked layers a multi-layer ceramic thermocompression heater according to an exemplary embodiment of the invention.

FIG. 4 is a diagrammatical exploded perspective view illustration of the major layers of a multi-layer ceramic thermocompression heater according to an exemplary embodiment of the invention.

FIG. 5 is a diagrammatical cross-sectional side view illustration of the stacked layers a multi-layer ceramic thermocompression heater having a perimeter-biased trace with non-uniform spacing.

FIG. 6 is a diagrammatical top plan view illustration of a first, uniformly spaced center-biased heater trace pattern according to an exemplary embodiment of the invention.

FIG. 7 is a diagrammatical top plan view illustration of a second, non-uniformly spaced perimeter-biased heater trace pattern according to an exemplary embodiment of the invention.

FIG. 8 is a diagrammatical top plan view illustration of the first and second trace patterns of FIGS. 6 and 7 superimposed upon one another.

FIG. 9 is a diagrammatical exploded perspective view illustration of the major layers of a multi-layer ceramic thermocompression bonding heater having a cooling stack according to an exemplary embodiment of the invention.

FIG. 10 is a graphical illustration of an exemplary heating profile obtained from a uniformly spaced center-biased heater trace pattern comparing center and edge location temperatures.

FIG. 11 is a graphical illustration of an exemplary heating profile obtained from a non-uniformly spaced, perimeter biasedly heater trace pattern comparing center and edge location temperatures.

FIG. 12 is a graphical illustration of an exemplary heating profile obtained from simultaneously operating the patterns of FIGS. 10 and 11 and comparing center and edge location temperatures.

FIG. 13 is a tabular illustration of a second exemplary heating profile obtained from simultaneously operating the patterns of FIGS. 10 and 11.

FIG. 14 is a graphical illustration of the tabular data shown in FIG. 13.

FIG. 15 is a graphical illustration of the tabular data shown in FIG. 13 showing the temperature difference between center and edge locations.

FIG. 16 is a flow diagram showing some major steps in the bonding method according to an exemplary embodiment of the invention.

FIG. 17 is a diagrammatical cross-sectional side view illustration of a bonded chip and interposer.

FIG. 18 is an enlarged partial diagrammatical cross-sectional side view illustration of a bonded chip and interposer of FIG. 17.

FIG. 19 is a diagrammatical top plan view illustration of a first of a pair of non-uniformly spaced perimeter-biased heater trace pattern according to an alternate exemplary embodiment of the invention

FIG. 20 is a diagrammatical top plan view illustration of a second of a pair of non-uniformly spaced perimeter-biased heater trace patterns according to an alternate exemplary embodiment of the invention

FIG. 21 is a diagrammatical top plan view isobar illustration of temperature difference when operating the heater of FIGS. 19 and 20.

FIG. 22 is a diagrammatical perspective view illustration of the first and second perimeter biased heater trace patterns having non-uniform widths and spacings superimposed upon one another.

FIG. 23 is a diagrammatical cross-sectional side view illustration of the stacked layers a multi-layer ceramic thermocompression heater of FIG. 21 having a two perimeter biased heater traces with non-uniform widths and spacings.

FIG. 24 is a diagrammatical top plan view illustration of a first, uniformly space center-biased heater trace pattern surrounded by a coplanar perimeter-biased trace pattern according to an alternate exemplary embodiment of the invention

FIG. 25 is a tabular illustration of a second exemplary heating routine obtained from simultaneously operating the patterns of FIG. 24.

FIG. 26 is a graphical illustration of the tabular data shown in FIG. 25.

FIG. 27 is a graphical illustration of the tabular data shown in FIG. 25 showing the temperature difference between center and edge locations.

FIG. 28 is a diagrammatical cross-sectional side view illustration of a multi-layer ceramic thermocompression sintered heater body prior to pedestal formation according to an exemplary embodiment of the invention.

FIG. 29 is a diagrammatical cross-sectional side view illustration of the heater body of FIG. 28 during dicing.

FIG. 30 is a diagrammatical cross-sectional side view illustration of the heater body of FIG. 29 during the grinding away of material surrounding the pedestal.

FIG. 31 is a diagrammatical cross-sectional side view illustration of the heater body of FIG. 30 showing a small size pedestal and a larger size pedestal in dotted lines.

FIG. 32 is a graphical illustration of an exemplary multi-trace powering routines and resultant heating profile for a small pedestal heater.

FIG. 33 is a graphical illustration of an exemplary multi-trace powering routines and resultant heating profile for a large pedestal heater.

FIG. 34 is a flow diagram showing some major steps in a method for deriving optimized powering routines for a given die geometry and bonding requirements according to an exemplary embodiment of the invention.

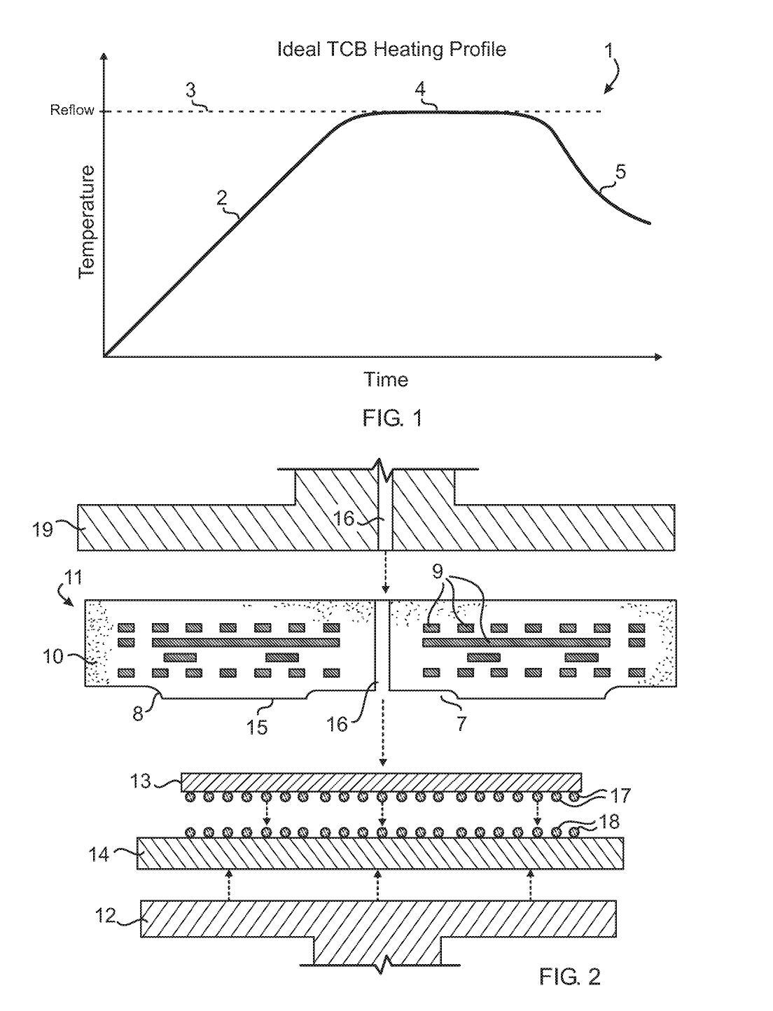

### DESCRIPTION OF THE EXEMPLARY EMBODIMENTS

The exemplary embodiment of the invention will be described by way of example in the field of the manufacture of a heatable and sensor-infused thermocompression bonding apparatus substrate. Thus, a thermocompression bonding substrate can be made primarily out of a ceramic material such as aluminum nitride (“AlN”) ceramic having a plurality of metallized heating element traces, thermal sensors in the form of so called “resistance temperature detector” (RTD) traces, electronic signal carrying and power interconnect traces, and grounded shielding traces using tungsten, and vias.

The substrate is manufactured using a multi-layer ceramic (“MLC”) process including the steps of tape casting, blanking, screening, metalization, stacking, laminating, debinding, sintering, flatfiring, lapping, polishing, grinding plating, and brazing for example.

Referring now to drawing, there is shown in FIG. 2 an improved thermocompression bonding apparatus heater 11 for use within a thermocompression bonding machine used to bond the spaced apart array of electrically conductive structures such as solder bumps 17 on an electronic part 13 or number of parts to a supporting part 14 or other electronic structure having its own co-aligned array of electrically conductive structures 18.

For example, the part 13 contacting the heater 11 can be an integrated circuit die having an array of electrically conductive bumps 17 oriented to electrically interconnect with a corresponding array of bumps 18 on the exposed surface of another part 14 such as an interposer for use in a microelectronic semiconductor integrated circuit package. It is important to note that the part or parts being heated by the heater can, for example be an integrated circuit die, an interposer, or electronic package or subsubstate, an electronic device such as a transistor, or other electronic structures having spaced apart electrically conductive structures such as copper pillars, tinned copper pillars, solder balls or bumps, or electrical contact pads.

A pressure plate 19 is oriented to carry the heater 11 which includes an number of electrical traces 9 within an electrically insulating ceramic body 10. The die 13 can be vacuum carried upon the substantially flat undersurface platform 15 of the heater by way of a vacuum channel 16 coursing through the heater and pressure plate and terminating at the platform surface in a number of vacuum grooves 7. The platform can be shaped in the form of a pedestal 8 to reduce the mass of the heater and have a smooth surface area shaped to closely conform with the shape of the die surface contacting it. The interposer 14 is supported upon a support plate 12. During bonding the two plates are alignedly pressed together. For many common applications the support plate 12 can be warmed to about 80 degrees centigrade.

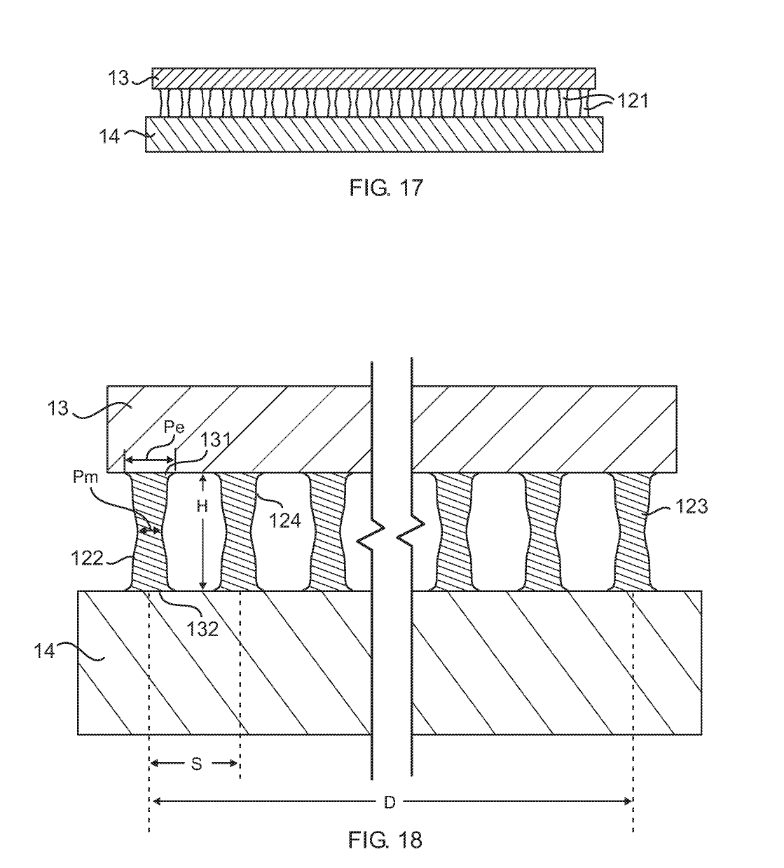

During bonding the heater 11 is heated, and the support plate 12 and pressure plate 19 are brought together under a force sufficient for thermocompression bonding to occur between the die and interposer where the interfacing bumps contact one another. During bonding the heater is energized to rapidly heat the bumps to the reflow temperature whereupon the force resisting compression reduces slightly. Upon detecting a reflow condition the compressing force is terminated and the plates drawn slightly apart to help avoid the reflowed bumps from mushrooming out, and bringing adjacent bumps too close together, possibly resulting in unwanted electrical shorts. The heater is denergized and the flowed material is allowed to cool and resolidify as spaced apart columns or pillars as shown for example in FIG. 17. At least one preferred exemplary heating profile will be described in detail further below.

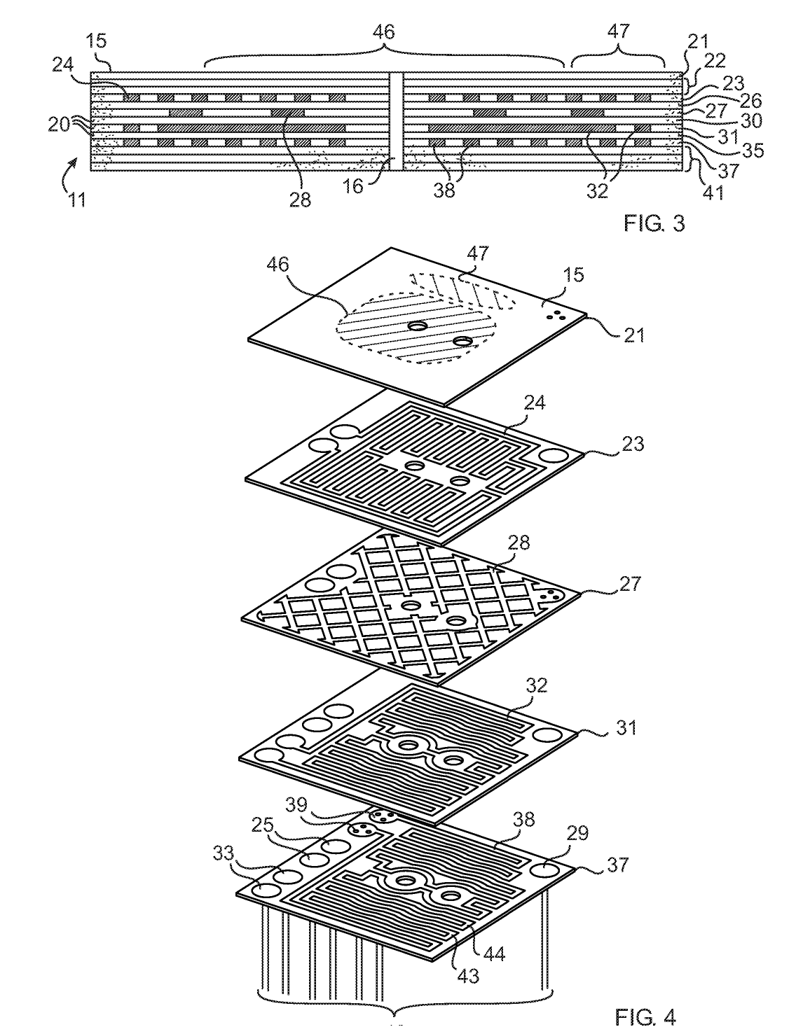

Referring primarily now to FIGS. 3 and 4, the heater 11 can be manufactured using a multi-layer ceramic (MLC) process by stacking, laminating and sintering a number of “green tape” layers 20. For simplicity a minimum number of layers are shown in the drawing. Those skilled in the art will understand that each layer can represent one or more layers of stacked “green tape”. Some of the layers are screened and metallization imprinted thereon to form the electrical traces and interconnections within the heater body. Those skilled in the art will further understand the simplified, stylized nature of the drawing for showing structures described. The physical geometries are often significantly more complex. (Note that the heater is shown in an inverted orientation from that of the heater shown in FIG. 2.)

A first interface layer 21 forms the platform surface 15 of the heater which interfaces with the substantially flat backing surface of the die or dice during bonding. The interface layer thus can form the substantially planar operational surface of the heater. The interface layer also hermetically seals the internal metalization of the heater from the outside environment. A number of intermediate layers 22 can separate the interface layer from the rest of the heater body and add thickness to the body for structural integrity purposes, to enhance hermeticity, and to improve electrical isolation. (For clarity, the intermediate layers are not shown in FIG. 4.)

Parallely spaced apart from the interface layer 21 is a temperature sensor layer 23 including a serpentine RTD trace 24 electrically connected across the layers of the heater through metallized vias to RTD contact lands 25. An intermediate electrically insulating layer 26 can separate the RTD layer from a grounded shielding layer 27 having an interconnected grid of traces 28 electrically connected across the layers of the heater to a grounding contact land 29. The shielding layer helps reduce electromagnetic radiation from reaching the RTD traces to induce noise.

Another intermediate electrically insulating layer 30 can separate the shielding layer 27 from a first heater element layer 31 which includes a serpentine first heater element trace 32 which electrically interconnects across the layers of the heater to first heater trace contact lands 33. Another intermediate electrically insulating layer 35 can separate the first heater element layer 31 from a second heater element layer 37 which includes a serpentine second heater element trace 38 which electrically interconnects across the layers of the heater to second heater trace contact lands 39. One or more intermediate layers 41 can seal the second heater element layer within the heater and provide additional structural integrity to the heater body. A number of electrical lines 40 electrically connect the contact lands of the heater with outboard electronics. Further it is understood that each of the heater elements can be separately energized.

It is understood that each heater element can be formed by a continuous serpentine trace lamellarly spaced apart or separated from the other heater element trace by intermediate layers. Further, each trace can run in a pattern having a number of successive switchback spaced apart curves or runs 43,44 to form successive loops which course beneath and supply heat to the platform of the heater. Further, a pattern of parallely spaced apart straight line segments of one element trace 32 can be oriented orthogonally to the pattern of parallely spaced apart straight line segments of the other element trace 38 in order to reduce magnetic induction between physically proximal traces, primarily from the heater traces to the RTD trace, and to more uniformly distribute heat across the heater platform. In this embodiment both heater traces have heater trace runs that have straight line segments that are substantially uniformly spaced apart. A vacuum channel 16 can be formed through the layers and terminate in one or more openings on the platform 15.

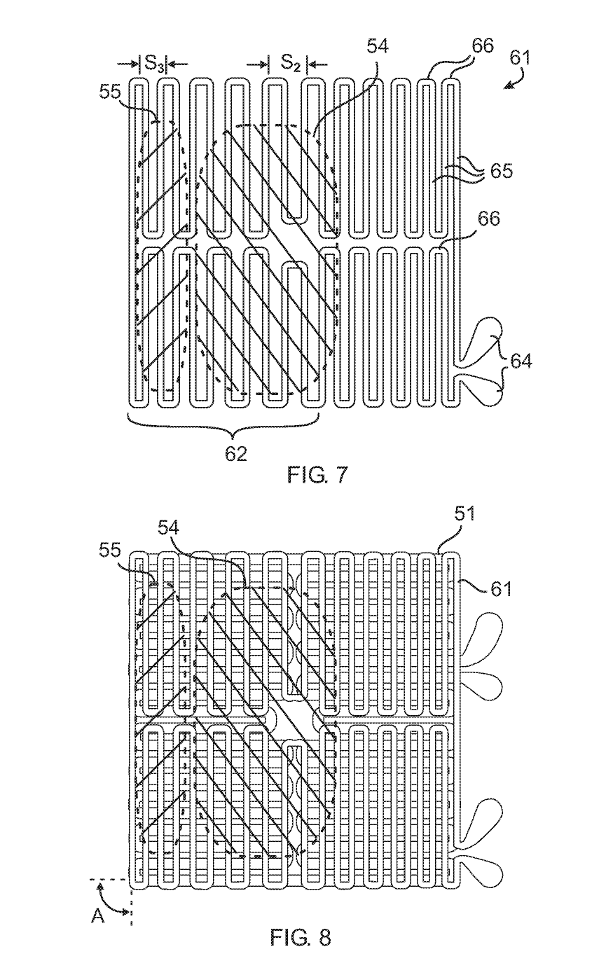

Further, the platform 15 of the heater can be characterized as having surface locations including a medial zone 46 and a peripheral region 47 located adjacent to, or peripherally spaced a distance apart from, the medial zone. Both the first heater element trace 32 and the second heater element trace 38 course beneath both the zone and the region locations. In this way, a trace can be said to be in thermal communication with the zone or region when the temperature of the region is determined to a significant extent by the proximity of part of the trace. Another way of characterizing the state of the trace being in “thermal communication” with a location on the platform can be by way of the top plan view projection or footprint of the trace upon the platform surface as shown for example in FIGS. 6-8. Those locations of the platform within the footprint of the trace segments can be said to be in thermal communication with the trace segments. Because the first and second theater traces can be energized independently, one trace can be powered in a manner that provides a center-bias to the heating profile while the other trace can be powered in a manner that provides a peripheral bias to the heating profile. For example the center-baised trace can be energized using a plateaued powering routine while the peripheral-biased trace can be energized using a more impulse based bell-shaped steeper ramp-up powering routine having a maximum at the onset of the intended plateau phase.

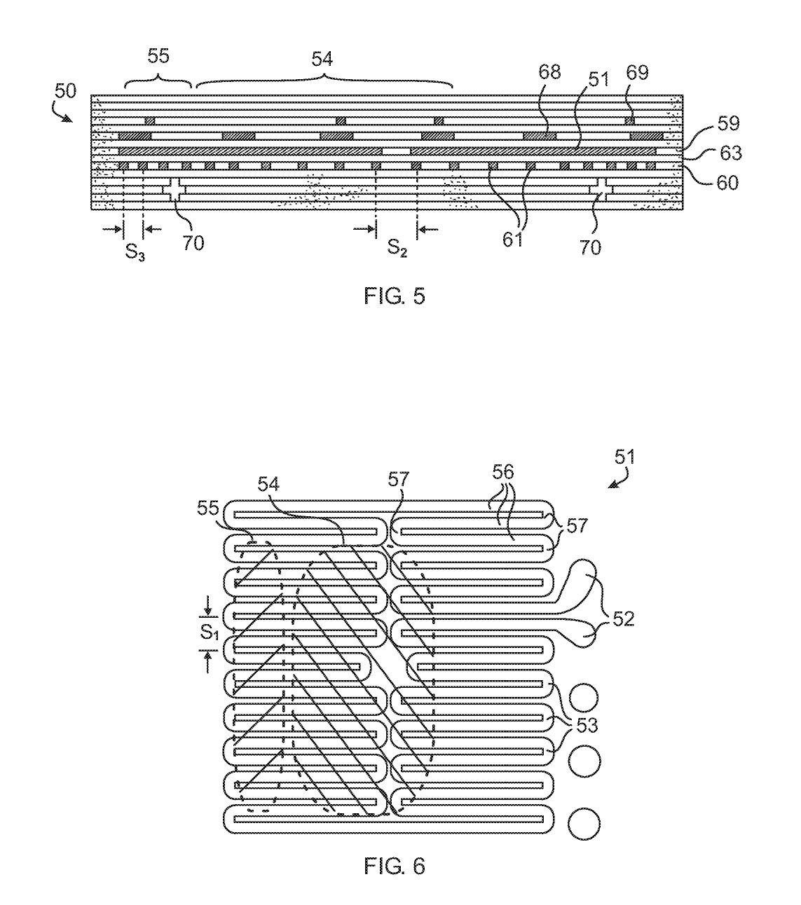

Referring now to FIGS. 5-8, there is shown an alternate embodiment of an improved thermocompression bonding apparatus heater 50 having a substantially planar first heater element trace 51 formed on a first layer 59 and a substantially planar second heater element trace 61 formed on a second layer 60 parallely spaced apart from the first layer by an intermediate layer 63. One or more ground traces 68 and RTD traces 69 can be formed on other layers. Optional conduits 70 for carrying cooling fluids can be formed in other layers.

The first element trace 51 has a trace pattern formed by a single serpentine trace running between a pair of powering contact pads 52 forming a plurality of adjacently spaced apart heating element runs 53 and having straight line segments 56 having substantially uniform spacing S₁, and running under both a medial zone 54 and a peripheral region 55 locations of the heater platform. In other words, the spacing between the straight line segments of an adjacent pair of loops running below the medial zone is substantially the same as the spacing between an adjacent pair of straight line segments of loops running below the peripheral region. It is further shown that the pattern of curves can be in the form of a set of substantially uniformly spaced apart parallel lines 56 and perpendicular arcuate sections 57 linking the lines. Operating a trace having this geometry results in a center-biased heating profile.

A second substantially planar heater element trace 61 can have a trace pattern formed by a single serpentine trace running between a pair of powering contact pads 64. The pattern can have a set of adjacently spaced-apart heating element curves 62 laid in a progressively denser formation between the medial zone 54 and the peripheral region 55. In other words, the spacing S₂ between an adjacent pair of straight line segments of loops located within the medial zone is greater than the spacing S₃ between an adjacent pair of straight line segments of loops located within the peripheral region. It is further shown that the pattern of curves can be in the form of a set of parallel lines 65 and substantially perpendicular arcuate sections 66 linking the lines. Therefore, it can be said that the second heater element trace pattern can have substantially non-uniform spacing between parallely spaced apart line segments. Operating a trace having this geometry results in a perimeter-biased heating profile.

By having non-uniform spacing, the second trace can generate heat flux through one area 54 of the trace footprint that is different from the heat flux through a different area 55 of the trace footprint. In other words, by running the pattern of trace lines more closely together the heat flux in the peripheral region can be increased, while the heat flux through the medial zone can be reduced over the fluxes expected by uniformly spaced apart trace patterns.

FIG. 8 shows that the second heater element trace 61 having non-uniform spacing between parallely spaced apart line segments can be selected to have a footprint similar to the first heater element trace 51 having substantially uniformly spaced apart line segments so that the peripheral extent of the two heater element traces is substantially commensurate when the traces are superimposed over one another in a vertically parallely spaced apart manner. In other words, both heater elements can course under common locations or areas of the heater platform.

Further, it can be clearly understood that the set of uniformly spaced apart parallel line segments of a first heater element trace pattern can be run in a first orientation and the trace pattern of the second heater element can be selected to have parallely spaced apart parallel line segments which run at second orientation forming an angle A relative to the first orientation. That angle can be selected to be approximately 90 degrees so that the parallel line segments of one trace are substantially perpendicular to the lines of the other trace. In this way, the combined heat flux generated by the two heaters can be better dispersed and currents in one trace are less likely to magnetically induce unwanted currents in the other heater or RTD traces.

Thus it shall be understood that the two superimposed heater traces can be adapted to have a substantially commensurate footprint existing beneath the medial zone 54 and the peripheral region 55. The medial zone can be referred to as the “center” part of the footprint, and the peripheral region as the “edge” part of the footprint.

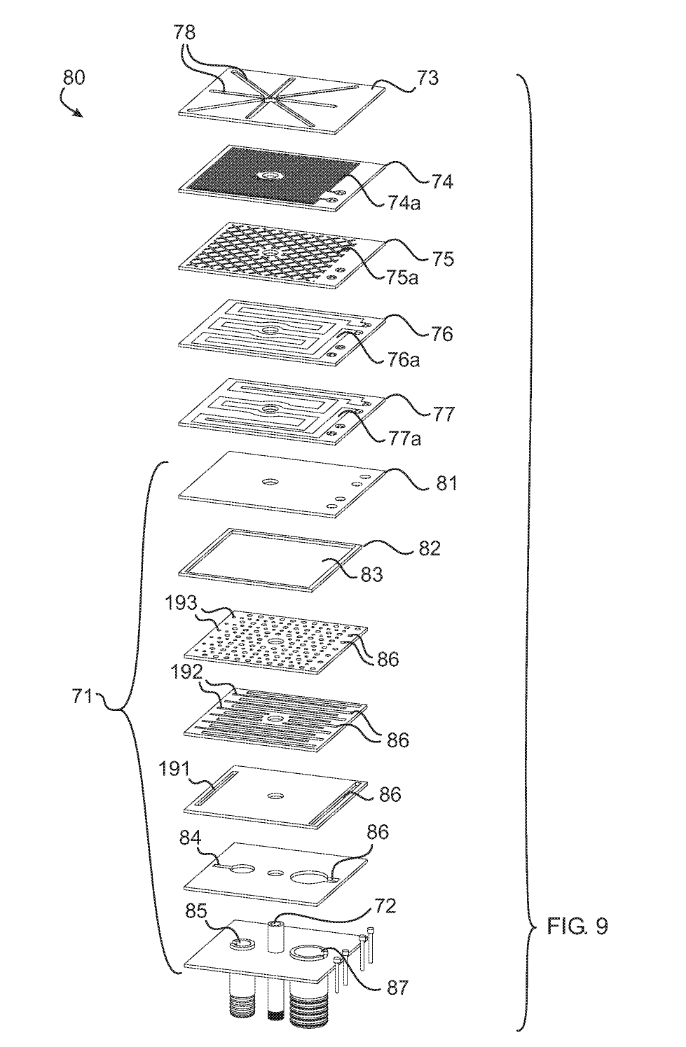

As shown in FIG. 9, a plural trace heater 80 can be combined with a cooling stack 71 in a single MLC body. A central vacuum channel 72 runs through the body and opens on a platform surface 73 having an array of grooves 78 emanating from the channel toward different regions of the platform surface and are oriented to secured secure the die to the platform surface by vacuum during operation. Successively, below the platform is an RTD layer 74 carrying an RTD trace 74a, a ground plane layer 75 carrying a ground trace 75a, a first center-biased heater element trace layer 76 carrying a heater trace 76a to be operated using a center-bias powering routine, a second perimeter-biased heater element trace layer 77 carrying a heater trace 77a to be operated using a perimeter-bias powering routine, followed by the layers forming the cooling stack 71.

The cooling stack 71 is formed by a number of successive layers starting with an interface layer 81 which separates the nearest heater trace layer 77 from a reservoir layer 82 having an enlarged heat transfer reservoir 83 for carrying a flow of fluid coolant such as air. Cool air is supplied to the reservoir through a supply manifold 84 connected to a cool air supply source line 85 while heated air is withdrawn from the reservoir through an exhaust manifold 86 connected to an exhaust return line 87. Both the supply and exhaust manifolds are formed by a number of stacked layers having interconnected vias formed therein.

Specifically, both the cool fluid supply manifold 84 and the warm fluid exhaust manifold 86 can be formed by similar via structures in the successive layers. Thus the supply and exhaust lines, the manifolds and the reservoir form a network of cooling vias extending through a plurality of adjacently stratified layers. The cool air supply manifold 84 can include a trunk portion 191 from which a number of branch portions 192 emanate. Each one of the branch portions includes a plurality of spaced apart feeder ducts 193 leading between the branch portion and said reservoir. The exhaust manifold has a similar form, however since it is carrying fluid at a higher temperature, the size of the ducts, branches and trunk can be enlarged. In this way the supply ducts can form a uniformly spaced apart grid which can supply cooling fluid to the reservoir in a highly dispersed way. Similarly, the exhaust ducts remove warmed fluid in a similarly dispersed way. This results in more uniformly rapid cooling than less dispersed supplies and exhausts.

It shall be understood that the above network of vias can have their geometry adjusted to adjust the flow of fluid to regions of the reservoir requiring more rapid cooling.

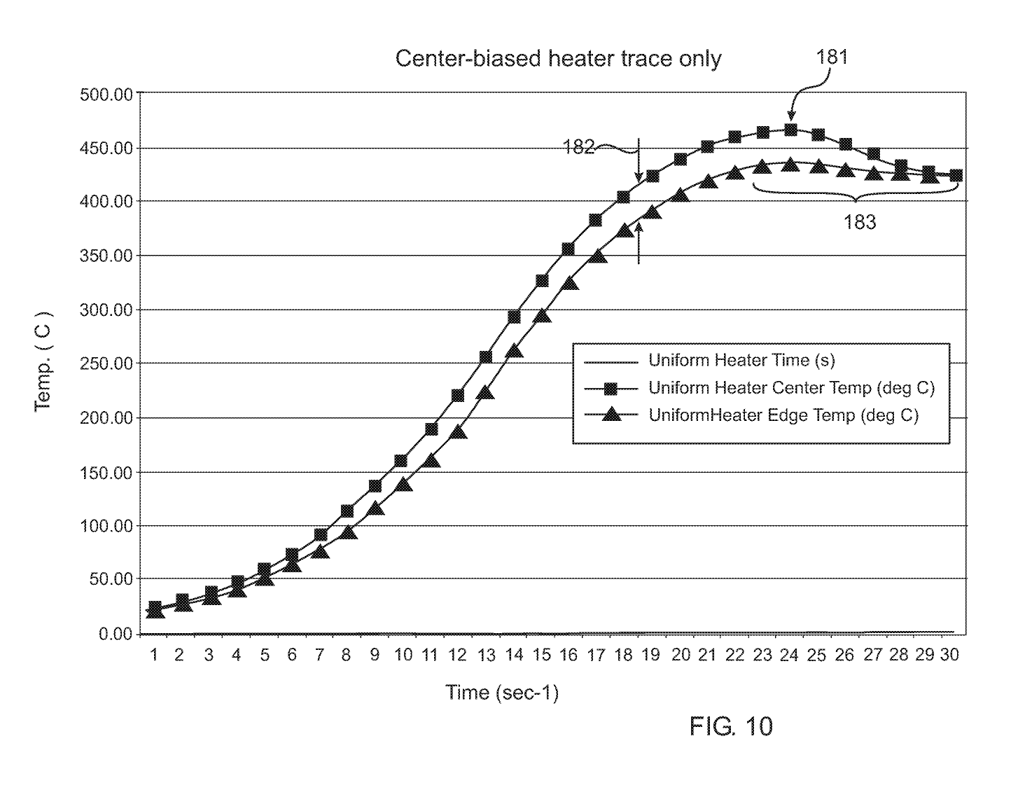

Referring now to FIGS. 10-12, it is shown that the simultaneous operation of the two heater elements generate a combined temperature profile superior to the profile achieved when each heater element is operated alone. Further, the temperature differential between the center and edge parts of the trace pattern footprint and thus the platform is reduced.

Specifically, FIG. 10 shows a temperature profile for the first, center-biased heater element trace 51 or “uniform heater trace” when it is operated alone. The profile shows a significant differential 182 between the corresponding temperatures in the center part and the edge part of the platform where the center temperature is much hotter than the edge temperature during rapid temperature ramp-up. Also shown an elevated temperature hump 181 occurring at the onset of the plateau phase 183 of the profile.

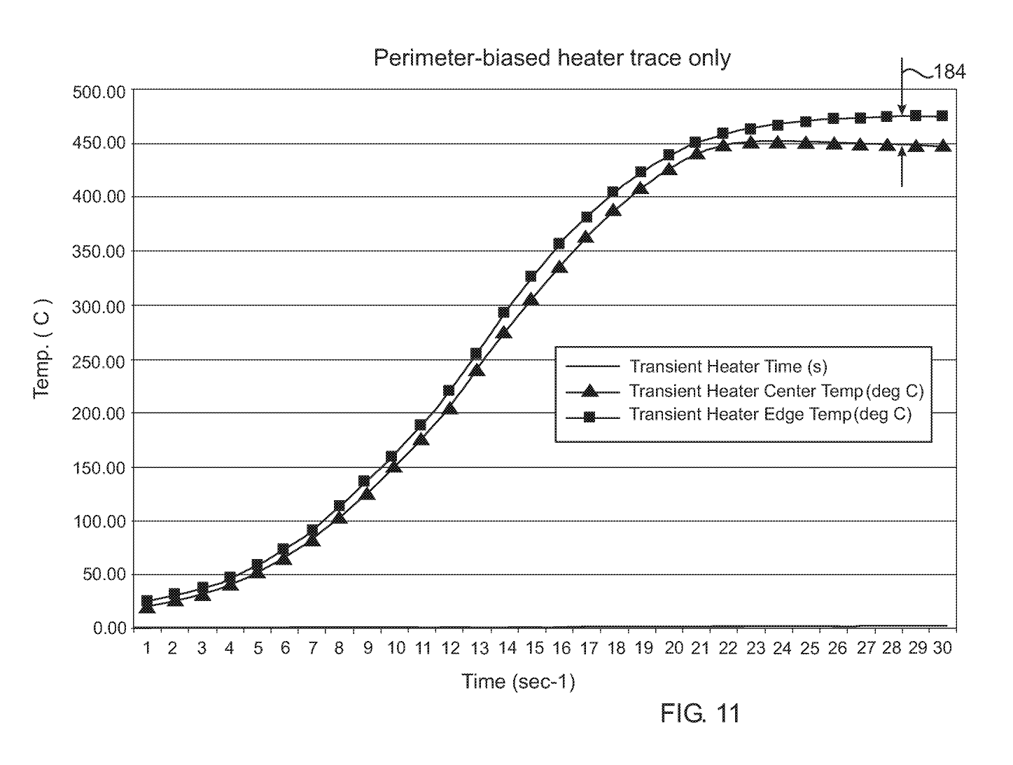

FIG. 11 shows a temperature profile for the second, non-uniformly spaced, perimeter biased heater element trace 61 when it is operated alone. Although the profile shows the center and edge temperatures closer to one another during rapid temperature ramp-up, there is a significant differential 184 between them during the plateau phase of the profile where the edge temperature becomes much hotter than the center temperature over time.

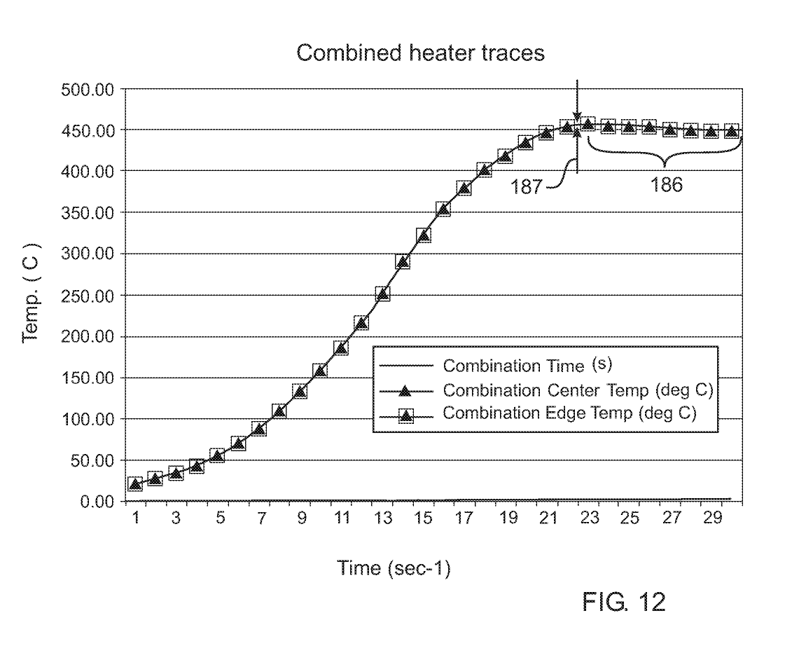

FIG. 12 shows that the combined operation of both traces using separate energization or powering routines results in a temperature profile having a substantially constant temperature plateau phase 186 and the temperature differential 187 between the center and edge regions that is significantly reduced to within 10 degrees centigrade.

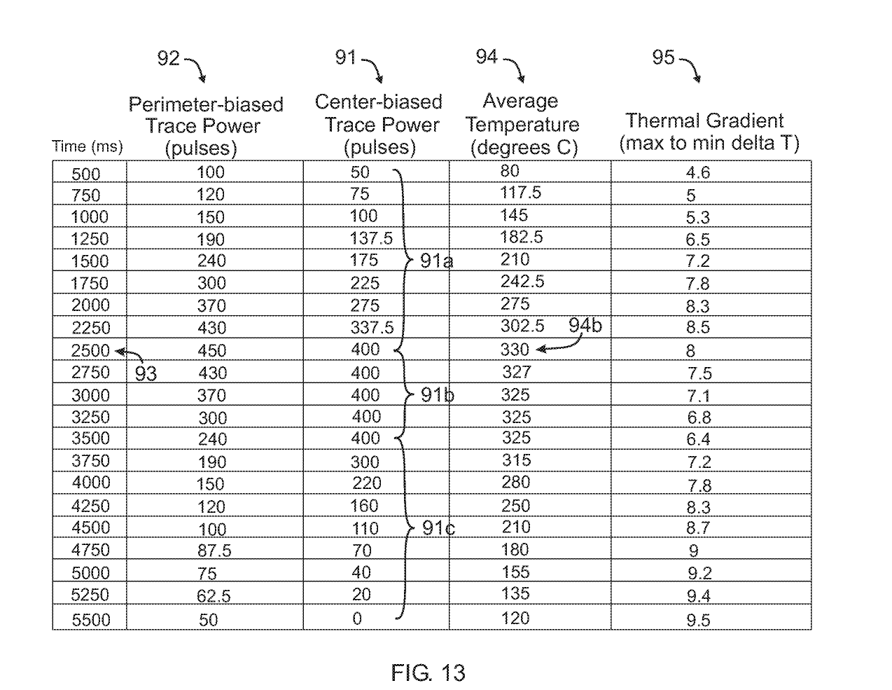

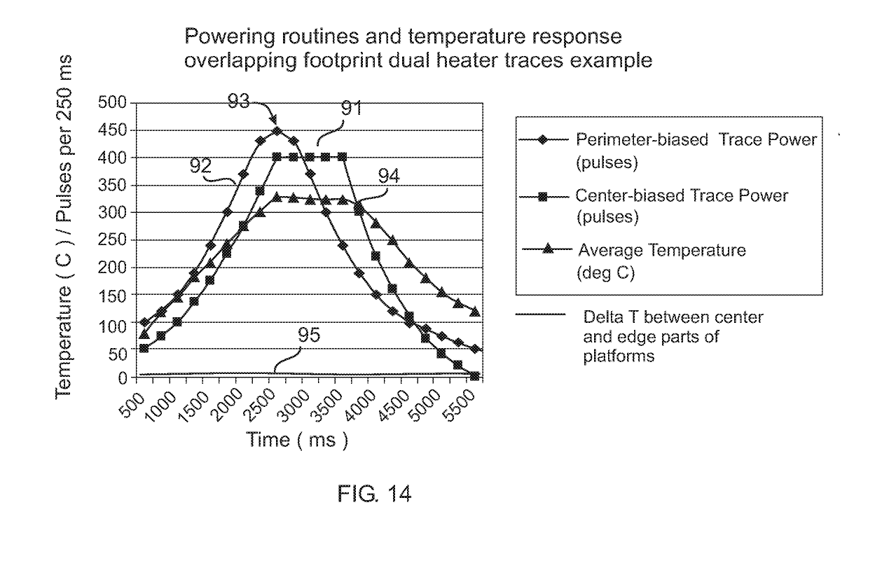

Referring now to FIGS. 13 and 14, the two heater elements can be operated in the following manner. The table of FIG. 13 as graphed in FIG. 14 shows that the first heater trace is energized according to a center-biased routine 91 which is similar to the ideal desired temperature profile having a substantially partial bell-shaped ramp up phase 91a, a constantly powered plateau phase 91b and a substantially partial bell-shaped power down phase 91c. The second heater is energized according to a perimeter-biased routine 92 having substantially a bell-shape having a maximum coinciding in time 93 with the beginning of the plateau phase 91b of the first center biased heater profile 91. The powering is conveniently expressed in terms of a variable number of uniform amplitude and duration pulses occurring within a uniform relatively small time frame, in this case 250 milliseconds. The ramp-up phase of both traces exhibit only a brief period of rapid high powering which at about 350 degrees centigrade per second, whereas the average ramp-up remains at about 200 degrees centigrade per second.

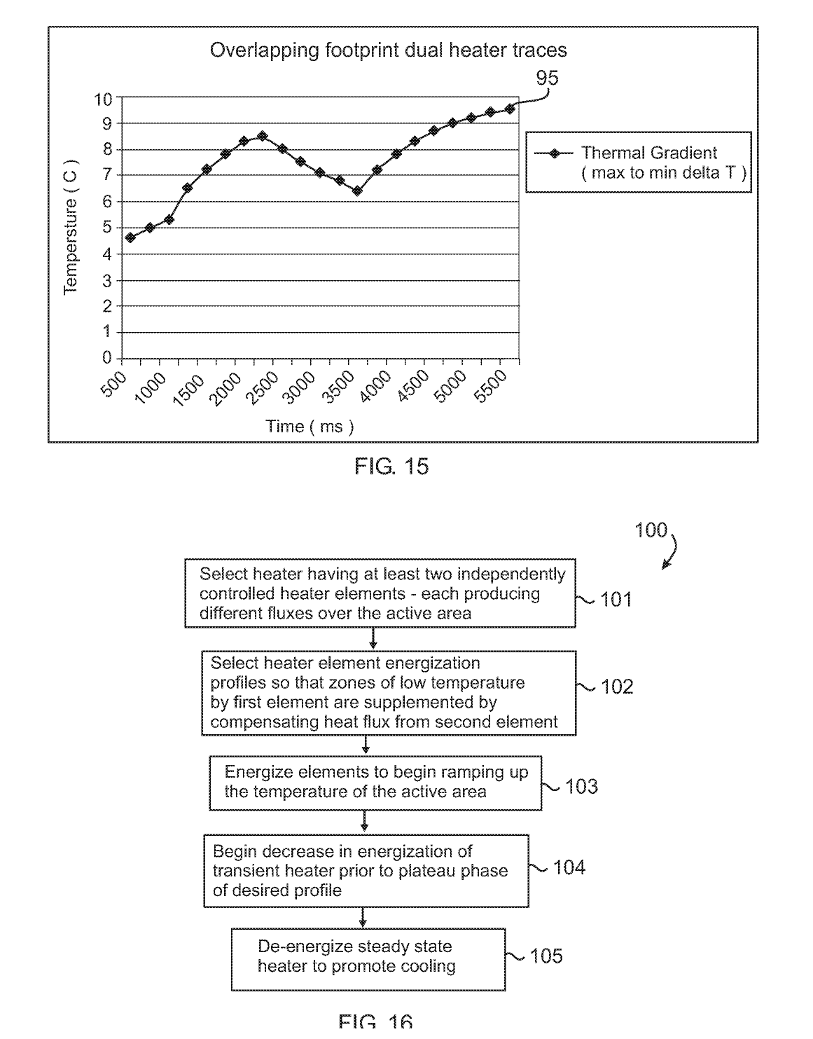

The resultant average temperature on the platform as detected by the RTD trace shows a profile 94 very close to ideal. Further, it can be seen that the maximum powering 93 of the first, perimeter biased heater occurs just prior to the onset 94b of the intended plateau phase of the average temperature on the platform. Further, the maximum temperature differential 95 at any given time across the entire area of the platform, in this example, is no greater than about 10 degrees centigrade, and as graphed more clearly in FIG. 15.

The result is a thermally uniform heater platform which is substantially isothermal across its active surface area platform. In other words, the platform provides substantially uniform temperatures across its active surface area for heating a carried chip during thermocompression bonding. In this context, substantially uniform temperatures will depend on the application of the heater. However for most TCB applications a temperature differential of no more than about 10 degrees centigrade which is about 3 percent difference, either plus or minus, can be said to be substantially uniform.

A further advantage of the above heater is that the power routines of the plural heater traces can be adjusted according to the parts being bonded. In other words, for smaller, low-mass parts the powering routine can be adjusted lower, whereas for larger, higher mass parts the power routines can be adjusted higher.

It is important to recognize that the powering routines can be easily adjusted to obtain vastly different heating profiles. Various adjustable powering routine parameters can include: shifting the entire curves in time; steepening or shallowing the ramp-up phases; raising, lowering, extending or shortening any plateau phases; and, steepening or shallowing the ramp-down phases.

Referring now to FIG. 16 there is disclosed a method 100 for controlling the temperature of a thermocompression bonding heater platform. The method includes selecting 101 a heater having at least two separately energizable heater elements that each provide a different heat flux to various locations of an actively heated platform for carrying one of the parts being bonded.

The two elements are also selected 102 so that operation of the first element will result in specific portions of the active area receiving less heat than ideal during the heating profile. The second element is selected to provide additional heat to those specific portions at specific times. In other words, the thermal flux generated by one of the elements will be deficient at some time and place on the surface. The other element can be selected and energized to provide additional flux at one or more of the deficient locations.

Thus each of the two heaters can be used differently. The first heater can be used as a center-biased heating element which has a substantially uniformly spaced trace pattern and is intended to be energized according to a center-bias routine. The second heater element can have a non-uniformly spaced trace pattern and can be used as a perimeter-biased heating element which can be energized preimeter-bias so as to overcome deficiencies in the spacial and temporal uniformity of the heating created by the uniformly spaced heater element.

During bonding, both elements are energized 103 to initiate the ramp up of the profile. This will tend to heat the center part of the active area of the platform more than the edges. In order to address this potential disuniformity, the transient heater is energized more forcefully just prior to the anticipated shortfall in heat expected by the first heater. This is because measured heat lags the energy input to the elements.

Just prior to the plateau phase of the ideal temperature profile, the perimeter-biased routine reaches a maximum and then begins decreasing 104. The ramp down phase of the perimeter-biased heater can also occur during the plateau phase of the center-biased heater.

At the end of the plateau phase, both elements are de-energized 105 allowing the area to cool. Alternately, active cooling can reduce the temperature this time.

The above process can result in a bonded die having more uniformly reflowed pillars than can be expected of many prior processes. The specifics of that greater uniformity can be characterized as follows.

In one embodiment the two heater traces are superimposed, one over the other so that each heater can supply heat to the same parts of the substantially planar operational surface carrying the component being thermocompression bonded thereon. In other words, a first heater element can fully heat the area necessary to heat the component being bonded and the second heater element can similarly fully heat the same area necessary to heat the component being bonded.

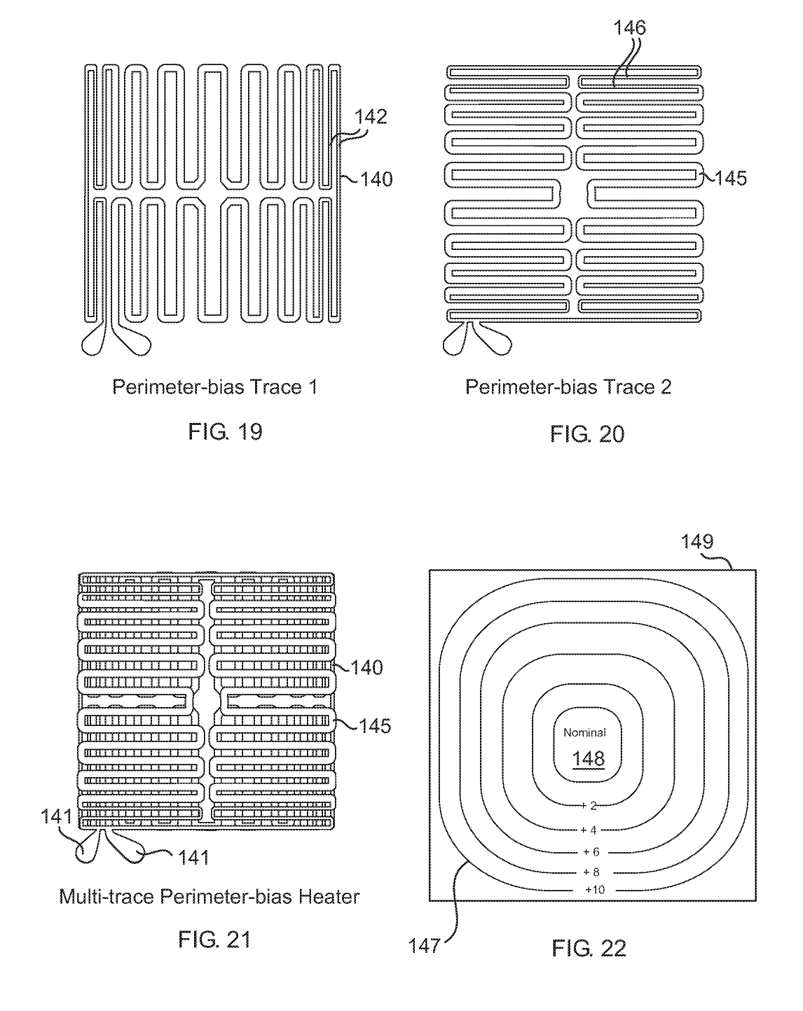

Referring now to FIGS. 17 and 18, there is shown a die 13 electrically bonded to an interposer 14 through a plurality of parallely spaced apart pillars 121. A first, left-most pillar 122 is located a max distance D from a farthest away, right-most pillar 123. These pillars are the farthest apart pair on the chip. For simplicity, a single linear row of pillars is shown in FIGS. 18 and 19. However, those skilled in the art will readily appreciate that in practice, the plurality of pillars often can arranged in a two dimensional array. In such a situation, the farthest apart pair of pillars would typically be located at diagonally opposite corners.

An adjacent pillar 124 nearest to the first pillar 122 is located a pillar spacing S apart. This is the shortest distance between adjacent pillars on a single chip.

Each pillar has a geometry that can be characterized as having a chip terminal end 131 and an opposite interposer terminal end 132 separated by a pillar height H. Both ends tend to have a similar diameter Pe. A medial part of the pillar has the narrowest pillar diameter Pm of the pillar.

Uniformity can be characterized where the maximum difference between the narrowest diameters Pm of all the pillars associated with a chip is less than 1%.

Referring now to FIGS. 19-23, in an alternate embodiment, the transient heater can be formed by a plurality of parallely spaced apart traces entitled Perimeter-bias Trace 1 140 and Perimeter-bias Trace 2 145 having commensurate footprints and shown in FIGS. 19 and 20 respectively. The first trace 140 can have non-uniform spacing between parallely spaced apart line segments 142. The second trace 145 can have non-uniform spacing between parallely spaced apart line segments 146 running orthogonally to the line segments of the first of the pair of traces. FIG. 21 shows the two traces can be superimposed and wired in parallel to create what functions as a single, multi-trace perimeter-biased heater pattern that is energized through a common pair of powering contact pads 141.

In this way, the heat flux generated by the combined pair of transient traces can have two dimensional heat flux variation as shown in the isobar of FIG. 22 where the peripheral temperature over a period of time can be, for example, 10 degrees Centigrade above 147 the nominal temperature in the center 148 of the heater platform 149 and within plus or minus 3.0 percent of the nominal center temperature. Further, the individual traces 140,145 can be designed in a relatively non-complex manner where density variation occurs along a single dimension. Two dimensional density variation can thus be achieved by combining two differently oriented traces. In this case the two traces are oriented in an orthogonal manner.

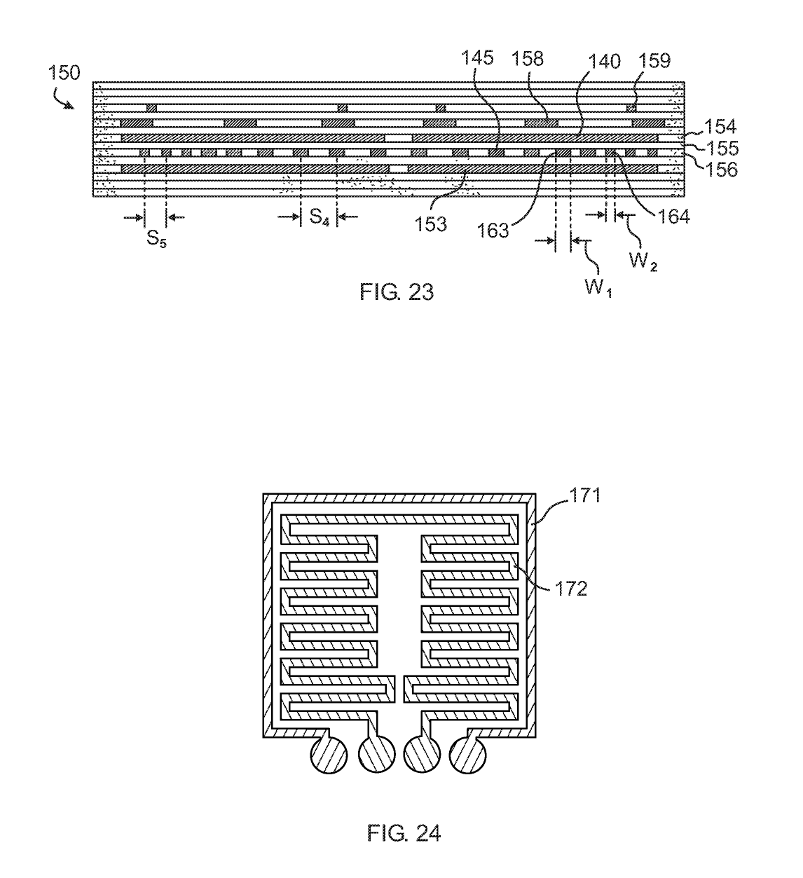

FIG. 23 shows that a thermocompression bonding heater 150 can be formed from a pair of parallely spaced apart perimeter-biased heater traces 140,145 having commensurate footprints and spaced apart from a third, center-biased heater trace 153. The first substantially planar, upper trace 140 is formed on a first layer 154. The second substantially planar, lower trace 145 is formed on a second layer 156 parallely spaced apart from the first layer by an intermediate layer 155. One or more ground traces 158 and RTD traces 159 can be formed on other layers. As with the prior embodiment, parallely spaced apart line segments of the first trace can be oriented at an angle to the parallely spaced apart line segments of the second trace, and that angle can be 90 degrees. Further the two transient heater traces can be wired in parallel an driven by the same powering routine described above.

The perimeter-biased heater traces 140,145 can have non-uniform spacing between the centers of parallely spaced apart line segments. For example, a first pair of adjacent spaced apart line segments can have a spacing S4 which is different from the spacing S5 between another adjacent pair.

Further, the smallest cross-sectional geometry area of the trace run can be non-uniform with respect to different segments of the same trace. The smallest cross-sectional geometric area of a trace at a given segment location is typically found by taking the cross-section plane perpendicular to tangent line of the trace curve at that point. Conveniently, the smallest cross-sectional area of a trace run can be changed by changing the width of the trace at various locations. In other words, the width W₁ of the trace segment 163 is larger than the width W₂ of the trace segment 164, resulting in a smallest cross-sectional area of trace segment 163 being larger than the smallest cross-sectional area of trace segment 164. By changing the width of the trace, the electrical resistance of the trace can be changed at various segments resulting in greater heat flux per length of trace along that segment at that location. In other words, the heat flux over a given length of trace can be adjusted by reducing or increasing the uniform width of the trace along that given length. In other words, the present apparatus allows for adjustment of the so-called number of “squares” or per unit length resistance of a given segment of trace.

FIG. 24 shows that the perimeter-bias trace 171 and the center-bias trace 172 can be formed to have disjoint footprints and can be coplanar. In this embodiment the perimeter-biased trace 171 can surround the center-biased trace 172. The advantage of being coplanar is reduced manufacturing costs and potential mass reduction in the heater.

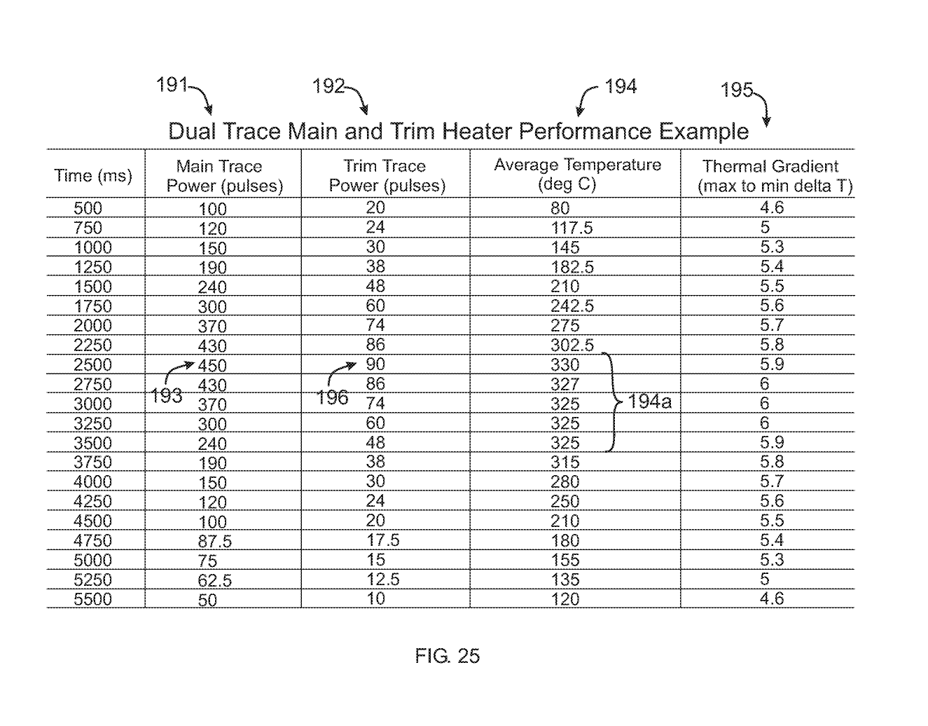

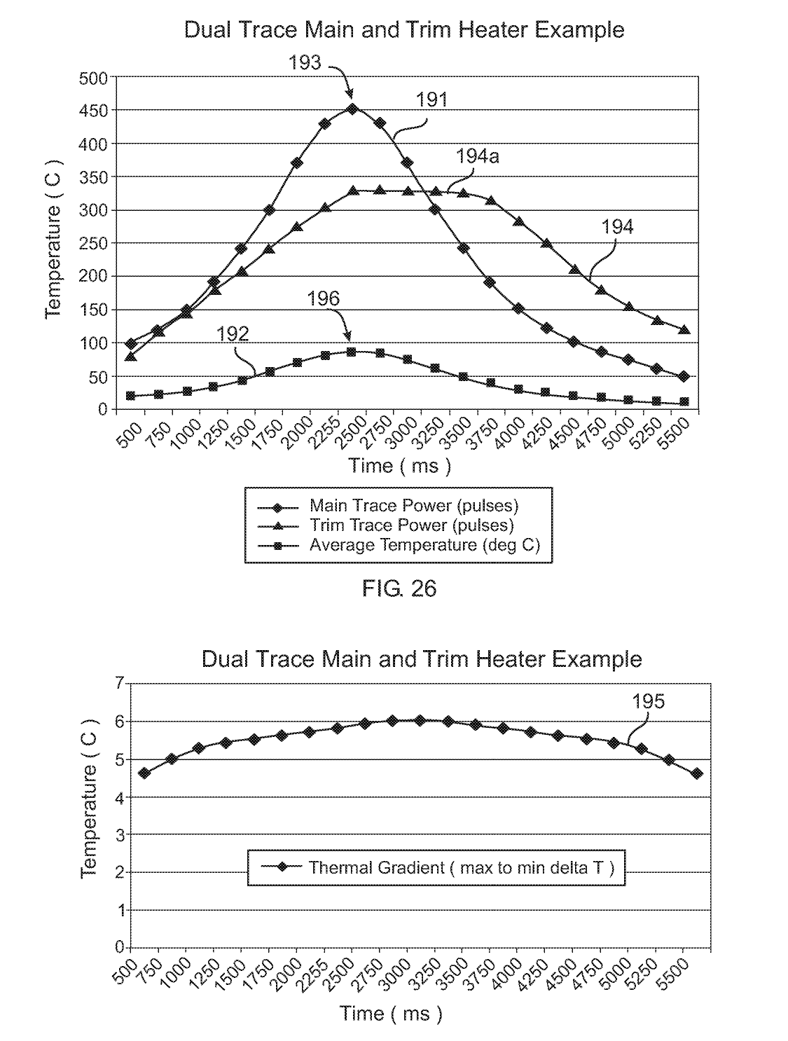

Referring now to FIGS. 25-27, the two heater elements of FIG. 24 can be operated in the following manner. The table of FIG. 25 as graphed in FIG. 26 shows that the “main” or center-bias trace 172 is energized according to a substantially bell-shaped center-bias routine 191 having a maximum similarly coinciding in time 193 with the beginning of the plateau phase 194a of the intended platform heating profile 194. The “trim” heater 171 is energized according to a substantially bell-shaped perimeter-biased routine 192 again having a maximum similarly coinciding in time 196 with the beginning of the plateau phase 194a of the intended platform heating profile 194. The powering is conveniently expressed in terms of a variable number of uniform amplitude and duration pulses occurring within a uniform relatively small time frame, in this case 250 milliseconds.

The resultant average temperature on the platform as detected by the RTD trace shows a profile 194 very close to ideal. Further, it can be seen that the maximum powering 193 of the first, perimeter biased heater occurs just prior to the onset of the intended plateau phase 194a of the average temperature on the platform. Further, the maximum temperature differential 195 at any given time across the entire area of the platform, in this example, is no greater than about 6 degrees centigrade, and as graphed more clearly in FIG. 27, and which falls within plus or minus 2 percent.

Although the above embodiments utilize the stacking of substantially planar layers of green tape, the topographically similar layers can have three-dimensional shapes such as nested curves, saddles, coaxial cylinders, or co-centric spheres for example. In this way, by using coaxial, radially adjacent cylindrical layers, cylindrical, highly controllable heaters can be formed.

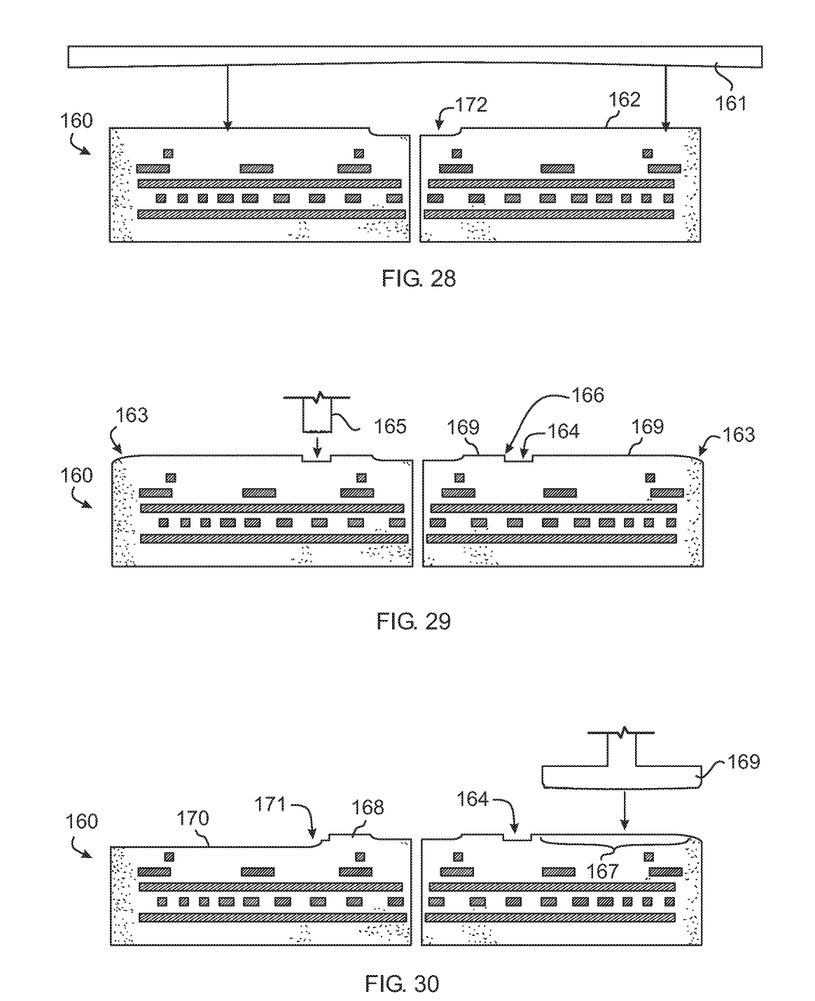

Referring now to FIGS. 28-32, the above embodiments can provide a greater flexibility as to heating profiles. In other words, a heater/cooler having essentially the same layout of traces can be adapted and operated in bonding dice having vastly different masses and geometries. For example, the above multi-trace heater/cooler can be easily adapted to bond both smaller parts using 6 mm square pedestal and larger ones using 40 mm square pedestal. Smaller parts tend to have lower mass and geometries having between about 5:1 and 10:1 ratio of length to thickness, and tend to ramp up their temperature relatively quickly, such as greater than 200 degrees centigrade per second. Larger parts tend to have higher mass and geometries having between about 15:1 and 25:1 ratio of length to thickness, and tend to ramp up their temperature relatively slowly, such as greater than 100 degrees centigrade per second on average.

The heater/cooler can be adapted to a particular die size or type by simply machining a standard sintered body differently. For example, as shown in FIGS. 28, a sintered heater body 160 including precut grooves 172 leading to the vacuum channel 174 is ground, lapped and polished using a lapping machine 161 to form an outer surface 162 that is typically flat to within about 25 micrometer (0.001 inch) for many common applications. This machine typically forms rounded edges 163 to the surface being polished as shown in FIG. 29.

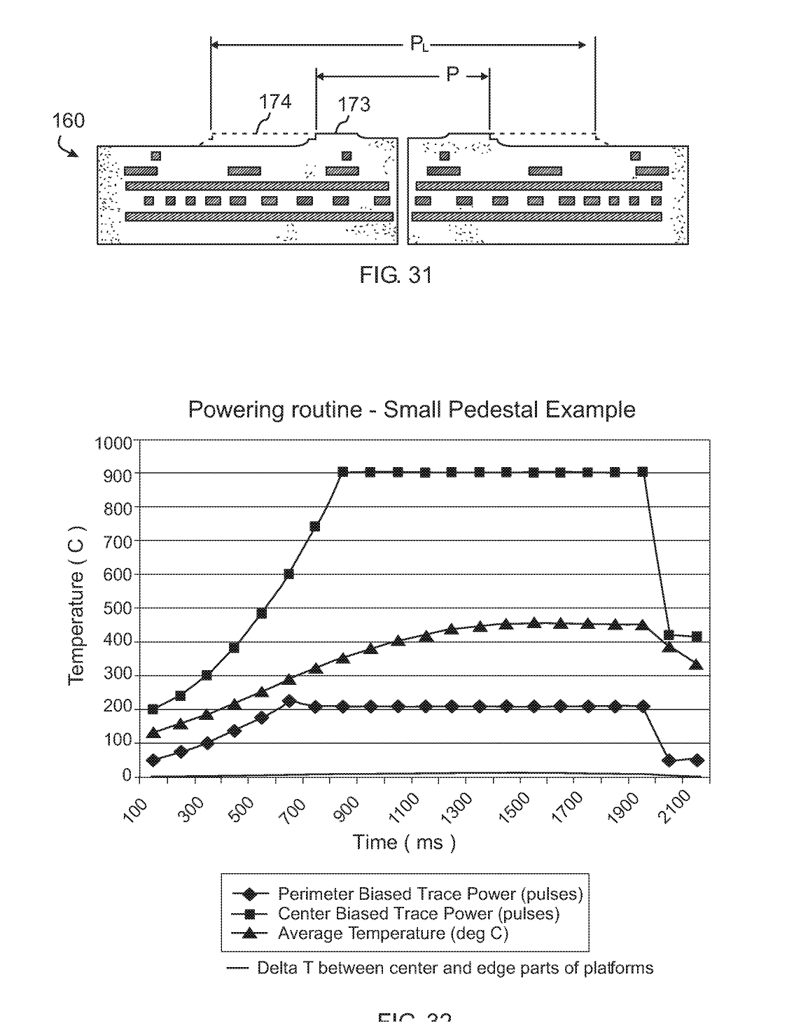

Next, as shown in FIG. 29, trenches 164 are cut into the polished surface 169 using a diamond impregnated dicing saw 165 to generally define a sharp edge 166 to what will become the heater platform. Thereafter, as shown in FIG. 30, the material 167 surrounding the heater platform pedestal 168 is ground away using a diamond impregnated grinding tool 169. The grinding step removes mass from the heater surrounding the pedestal and forms a gradual, rounded transition 171 in the outer surface of the heater between the ground-away portion 170 and the pedestal 173.

FIG. 31 shows that the pedestal 173 can have a dimension P corresponding to a small size intended for bonding a die having a smaller geometry and to minimize the mass of the heater. Alternately, the same sintered body can be machined according to the above steps to have a large pedestal 174 selected to mount a die having a larger geometry.

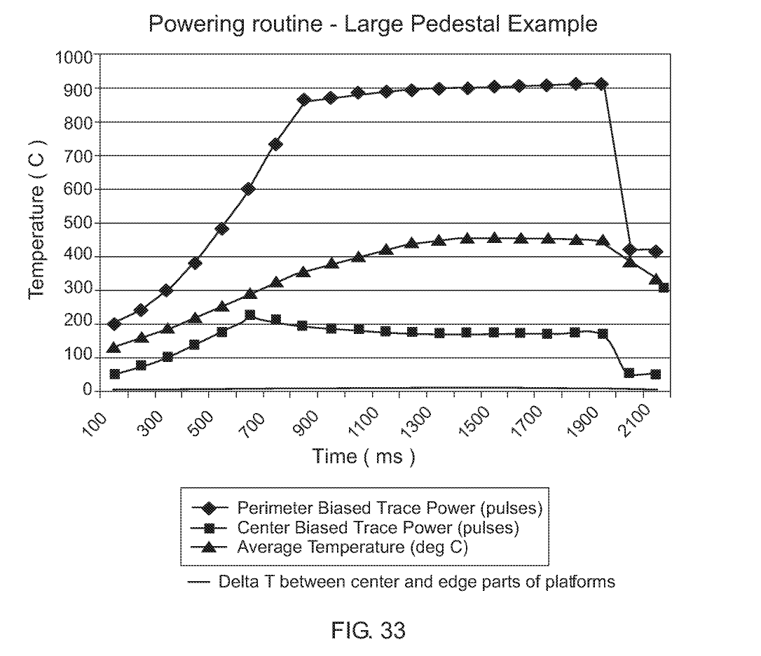

As shown in FIGS. 31-33, a small size pedestal 173 can for example be powered according to a power routine as shown in FIG. 32 favoring the perimeter bias. A large size pedestal 174 can be powered according to a power routine as shown in FIG. 33 favoring the center-bias. It is important to note that the exact same initial sintered body having the same heater trace patterns and cooling channels can be used to form heaters having the differently sized pedestals. However, the powering routines will be different.

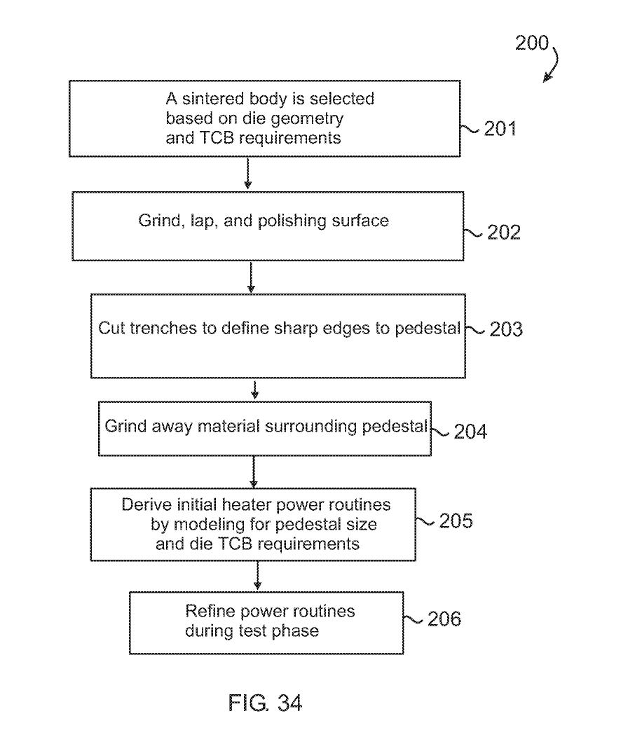

FIG. 34 shows the processing steps 200 used to optimize the powering routine for a given new die having a certain base geometry. First, a sintered body type is selected which can be formed into the heater used for particular die, given that die's geometry and TCB requirements 201. Next, the sintered body is ground, lapped and polished 202 to form the adequately flat and smooth platform upper surface of the eventual pedestal. Next, trenches are cut 203 to form the sharp upper surface demarcation of the pedestal. Next, the material surrounding the pedestal is ground away 204.

In this way, pedestals of widely different areas and even shapes can be formed into standard sintered heater bodies. This can significantly reduce manufacturing costs associated with TCB of different sized dice.

While the preferred embodiment of the invention has been described, modifications can be made and other embodiments may be devised without departing from the spirit of the invention and the scope of the appended claims.

What is claimed is:

1. A solid state electrical heater apparatus for heating the surface of a part, said apparatus comprises:
a part-contacting platform;
said platform including a medial zone and a peripheral region laterally spaced a distance apart form said medial zone;
a first heater element coursing along and being in thermal communication with said zone;
a second heater element spaced apart from said first heater element;
said second heater element coursing along and being in thermal communication with said region; and,
wherein said first and second heater elements are separately energizable.

2. The apparatus of claim 1, which further comprises:
said first element coursing along both said zone and said region; and
said second element coursing along both said zone and said region.

3. The apparatus of claim 1, wherein said first heater element disproportionately heats said zone more than said region over a given time frame; and, wherein said second heater element is adapted to provide proportionately greater heat flux to said region than said zone during a given energization period.

4. The apparatus of claim 1, wherein said first heater element comprises a first trace having a first circuitous pattern, and wherein said second heater element comprises a second trace having a second circuitous pattern.

5. The apparatus of claim 4, wherein said second circuitous pattern comprises a first pair of adjacent runs spaced apart by said first shortest distance and a second pair of adjacent runs spaced apart by a second shortest distance, wherein said first and second shortest distances are different.

6. The apparatus of claim 4, wherein said second circuitous pattern comprises:
a first run having a first smallest cross-sectional area; and,
a second run having a second smallest cross-sectional area, wherein said first and second smallest cross-sectional areas are different.

7. The apparatus of claim 4, wherein said first and second heater traces are coplanar and laterally spaced apart and wherein said second trace surrounds said first trace.

8. The apparatus of claim 1, wherein said first heater element is energized according to a first operation routine, and wherein said second heater element is energized according to a second operation routine, wherein operation of said heater elements simultaneously according to said routines results in a temperature difference across said platform of no greater than plus or minus 3 percent.

9. The apparatus of claim 1, wherein said first heater element is energized according to a first operation routine, and wherein said second heater element is energized according to a second operation routine, wherein operation of said heater elements simultaneously according to said routines results in a temperature difference across said platform of no greater than plus or minus 2 percent.

10. The apparatus of claim 9, wherein said first operation routine comprises a first heater element ramp up phase followed by a first heater element plateau phase followed by a first heater element ramp down phase; wherein said second operation routine comprises a second heater element ramp up phase followed by a second heater element ramp down phase.

11. The apparatus of claim 10, wherein said second heater element ramp down phase begins before or during said first heater element plateau phase.

12. The apparatus of claim 10, which further comprises:
said first heater element being energized during a portion of said plateau phase at no more than a constant plateau power level;
said second heater element operation routine comprising a second heater element maximum power level; and,
said maximum power level being greater than said constant plateau power level.

13. The apparatus of claim 4, wherein said first trace has a substantially planar first geometry commensurately overlaying a substantially planar second geometry of said second trace.

14. The apparatus of claim 13, which further comprises a RTD trace having a substantially planar geometry commensurately overlaying with said first geometry, interposed between said first heater trace and said surface.

15. The apparatus of claim 4, which further comprises:
a first grounding trace coursing along both of said region and said zone.

16. The apparatus of claim 4, which further comprises:
said heater being formed by a plurality of multilayer ceramic layers comprising:
aluminum nitride; and,
said traces comprising tungsten.

17. The apparatus of claim 16, which further comprises:
a first vacuum channel extending from said platform through a plurality of said layers.

18. The apparatus of claim 17, which further comprises:
a plurality of vacuum grooves emanating from said channel toward spaced apart regions of said platform.

19. The apparatus of claim 16, which further comprises at least one conduit extending through a plurality of adjacently stratified ones of said layers, wherein said at least one conduit is adapted to carry a cooling fluid.

20. The apparatus of claim 19, wherein said cooling fluid comprises air.

21. The apparatus of claim 16, which further comprises a network of cooling vias extending through a plurality of adjacently stratified ones of said layers, wherein said network is adapted to carry a cooling fluid comprising air.

22. The apparatus of claim 21, wherein said network comprises:
a reservoir;
a supply manifold leading from a source of cooling fluid to said reservoir; and,
an exhaust manifold from said reservoir to an exhaust return.

23. The apparatus of claim 22, wherein said supply manifold comprises:
a trunk portion;
a plurality of branch portions emanating from said trunk portion; and,
wherein each one of said branch portions includes a plurality of spaced apart feeder ducts leading between said one of said branch portions and said reservoir.

24. The apparatus of claim 4, wherein said second circuitous pattern comprises a plurality of interconnected, spaced apart runs wherein a spacing between adjacent runs progressively increases between said medial zone and said peripheral region.

25. The apparatus of claim 4, wherein said second circuitous pattern comprises a continuous flat spiral segment.

26. The apparatus of claim 4, wherein said second circuitous pattern comprises a continuous serpentine segment.

27. The apparatus of claim 26, wherein said continuous serpentine segment comprises:
a set of parallel lines; and,
perpendicular sections linking said lines.

28. The apparatus of claim 27, which further comprises:
said first circuitous pattern being topographically similar to the second circuitous pattern;
wherein said first circuitous pattern has trace lines substantially perpendicular to the parallel lines of said second pattern; and,
an electrically insulating layer between said patterns.

29. A thermocompression bonding apparatus comprises:
a heater substrate;
wherein said substrate comprises:
a substantially planar part-carrying upper surface having a medial zone and a peripheral region laterally spaced a distance apart form said medial zone; and,
a first heater element coursing under both of said region and said zone;
a first cooling conduit coursing under both of said region and said zone;
wherein said element comprises:
a first trace having a first circuitous pattern having a first segment coursing along said zone and a second segment coursing along said region;
wherein said first segment generates a first heat flux during an energization period, and wherein said second segment simultaneously generates a second heat flux during said energization period;
wherein said second flux is greater than said first flux;
whereby a unit area of said zone has a first temperature and a unit area of said region simultaneously has second temperature; wherein said first and second temperatures are within about 3 percent of one another.

30. The apparatus of claim 29, which further comprises:
said second segment has an electrical resistance per unit length of trace greater than said first segment.

31. The apparatus of claim 29, which further comprises a network of cooling vias extending through a plurality of adjacently stratified ones of said layers, wherein said network is adapted to carry a cooling fluid comprising air.

32. The apparatus of claim 31, wherein said network comprises:
a reservoir;
a supply manifold leading from a source of cooling fluid to said reservoir; and,
an exhaust manifold from said reservoir to a an exhaust return.

33. The apparatus of claim 32, wherein said supply manifold comprises:
a trunk portion;
a plurality of branch portions emanating from said trunk portion; and,
wherein each one of said branch portions includes a plurality of spaced apart feeder ducts leading between said one of said branch portions and said reservoir.

34. The apparatus of claim 31, which further comprises:
a second heater element spaced apart for said first heater element.

35. The apparatus of claim 29, which further comprises:
said second heater element coursing under both of said region and said zone; and,
wherein said first and second heater elements are separately energizable.

36. The apparatus of claim 29, which further comprises:
said first heater element comprising a first serpentine trace residing substantially within a first plane;
said second heater element comprising a second serpentine trace residing substantially within a second plane;
said first plane being parallely spaced apart from said second plane.

37. A method of controlling the temperature of a thermocompression bonding heater substrate, said method comprises:
selecting a heater substrate comprising:
a substantially planar operational surface comprising a medial zone and a peripheral region spaced a lateral distance apart from said medial zone;
a first heater element trace coursing along said zone;
a second heater element trace spaced apart for said first heater element trace;
said second heater element trace coursing along said region; and,
wherein said first and second traces are separately energizable;
energizing said first trace according to a center-biased energization routine;
simultaneously energizing said second trace according to a perimeter-biased energization routine; and,
ceasing energizing one of said traces during a time when the other of said traces is being energized;
whereby the simultaneous temperatures of said region and said zone are kept within about 3 percent of one another.

38. The method of claim 37, which further comprises:
said first trace coursing along both said zone and said region; and
said second trace coursing along both said zone and said region.

39. The method of claim 38, which further comprises:
said center-biased energization routine having a plateau phase.

40. A thermocompression bonded structure comprises:
an interposer;
at least one integrated circuit chip;
a plurality of spaced apart conductive metal pillars electrically interconnecting said at least one chip to said interposer;
wherein each of said pillars has a geometry comprising a height dimension, a top end diametric dimension, and a medial diametric dimension potentially different from one another;
wherein said height dimensions range between one percent of one another;
wherein said top end diametric dimensions range between one percent of one another; and,
wherein said medial diametric dimensions range between one percent of one another.

41. A method for optimizing the powering routine for a TCB heater, said method comprises:
selecting a sintered heater blank which can be machined to form an intended heater;
first grinding, lapping and polishing a platform surface of said intended heater;
cutting a demarcation of a pedestal into said surface;
grinding away an amount of material surrounding said pedestal;
modeling a preliminary heating routine from parameters associated with said die and said intended heater;
performing a test run of said intended heater using said preliminary heating routine; and,
adapting said preliminary heating routine into a final heating routine based on results of said performing.
